(19) United States
(12) Patent Application Publication
(10) Pub. No.: US 2008/0232077 A1
(43) Pub. Date: Sep. 25, 2008

(54) CONVERSION SUBSTRATE FOR A LEADFRAME AND THE METHOD FOR MAKING THE SAME

(75) Inventors: Che-Yuan Chang, Kaohsiung (TW); Yao-Ting Huang, Kaohsiung (TW)

Correspondence Address: VOLENTINE & WHITT PLLC, ONE FREEDOM SQUARE, 11951 FREEDOM DRIVE SUITE 1260, RESTON, VA, 20190, US

(73) Assignee: ADVANCED SEMICONDUCTOR ENGINEERING, INC., Kaohsiung (TW)

(21) Appl. No.: 12/052,056

(22) Filed: Mar. 20, 2008

(30) Foreign Application Priority Data
Mar. 21, 2007 (TW) 096109645

(51) Int. Cl. H05K 7/02; H05K 3/10

(52) U.S. Cl. 361/808; 29/885

(57) ABSTRACT

The present invention relates to a conversion substrate for a leadframe and the method for making the same. The conversion substrate comprises a core layer, a first copper layer, a first metal plating layer and a first brown/black oxide layer. The first copper layer is on a first surface of the core layer, and has a plurality of discontinuous sections. The first metal plating layer is on the first copper layer, and has a plurality of discontinuous sections. The first brown/black oxide layer is on the first copper layer, so as to protect the first copper layer. Thus, the polymeric solder mask is not used in the conversion substrate of the present invention, so that the metal plating layer will not be polluted, and the yield rate can be raised.

### BACKGROUND OF THE INVENTION

1. Field of the Invention

The present invention relates to a conversion substrate and the method for making the same, and more particularly to a conversion substrate for a leadframe and the method for making the same.

2. Description of the Related Art

FIG. 1 shows a schematic top view of a conventional leadframe. The leadframe 1 comprises four tie bars 11, a die pad 12, a conversion substrate 13, a die 14 and a plurality of wires 15. The tie bars 11 are used to support the die pad 12. The conversion substrate 13 is adhered to the die pad 12 via an adhesive (not shown). The conversion substrate 13 has an Ni/Au plating layer 131, and the Ni/Au plating layer 131 forms a plurality of circuits. The die 14 is adhered to the conversion substrate 13 via an adhesive 16 (FIG. 2), and has a plurality of pads 141. The pads 141 are electrically connected to the Ni/Au plating layer 131 via a plurality of wires 15, and the Ni/Au plating layer 131 is electrically connected to the electrically connecting portions of the leadframe 1 via a plurality of wires (not shown). Thus, the numbers of Input/Output are increased.

FIG. 2 shows a schematic cross-sectional view of a conventional conversion substrate. The conversion substrate 13 comprises an Ni/Au plating layer 131, a core layer 132, a first copper layer 133, a second copper layer 134, a first solder mask 135 and a second solder mask 136. The first copper layer 133 is disposed on the upper surface of the core layer 132. The second copper layer 134 is disposed on the lower surface of the core layer 132. The first solder mask 135 has a plurality of openings 1351, and does not cover the first copper layer 133 completely. The Ni/Au plating layer 131 is disposed on the first copper layer 133 in the openings 1351. The second solder mask 136 completely covers the second copper layer 134.

The conventional conversion substrate 13 has the disadvantage of usage of the first solder mask 135 and the second solder mask 136. The material of the solder masks is polymer, and the Ni/Au plating layer 131 is electroplated on the first copper layer 133. When the conventional conversion substrate 13 is performing a drying process after an etching process, the residual etchant will precipitate out from the solder masks to the surface of the Ni/Au plating layer 131. Thus, the Ni/Au plating layer 131 is polluted, which influences the wiring process of the wires 15 and the products appearance.

Therefore, it is necessary to provide an innovative and advanced conversion substrate for a leadframe and the method for making the same to solve the above problems.

### SUMMARY OF THE INVENTION

The present invention is directed to a conversion substrate for a leadframe which is mounted on a die pad of the leadframe. The conversion substrate comprises a core layer, a first copper layer, a first metal plating layer and a first brown/black oxide layer. The core layer has a first surface and a second surface. The first copper layer has a plurality of discontinuous sections, and is disposed on the first surface of the core layer. The first metal plating layer has a plurality of discontinuous sections, and is disposed on the first copper layer. The first brown/black oxide layer is disposed on the first copper layer, so as to protect the first copper layer. Thus, the polymeric solder mask is not used in the conversion substrate of the present invention, so that the metal plating layer will not be polluted, and the yield rate can be raised.

### BRIEF DESCRIPTION OF THE DRAWINGS

FIG. 1 shows a schematic top view of a conventional leadframe;

FIG. 2 shows a schematic cross-sectional view of a conventional conversion substrate;

FIGS. 3 to 9 show the schematic views of each step of the method for making a conversion substrate for a leadframe according to a first embodiment of the present invention;

FIG. 10 shows a schematic view of application of the conversion substrate for a leadframe according to the first embodiment of the present invention;

FIGS. 11 to 19 show the schematic views of each step of the method for making a conversion substrate for a leadframe according to a second embodiment of the present invention;

FIGS. 20 to 29 show the schematic views of each step of the method for making a conversion substrate for a leadframe according to a third embodiment of the present invention;

FIGS. 30 to 40 show the schematic views of each step of the method for making a conversion substrate for a leadframe according to a fourth embodiment of the present invention; and

FIGS. 41 to 53 show the schematic views of each step of the method for making a conversion substrate for a leadframe according to a fifth embodiment of the present invention.

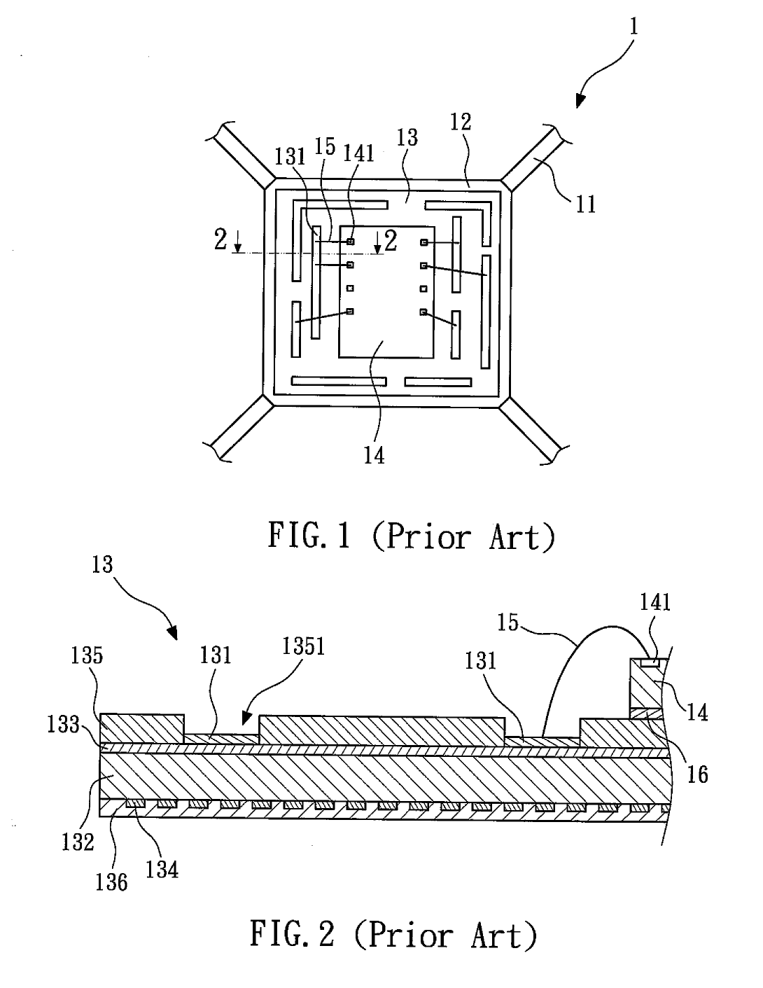

### DETAILED DESCRIPTION OF THE INVENTION

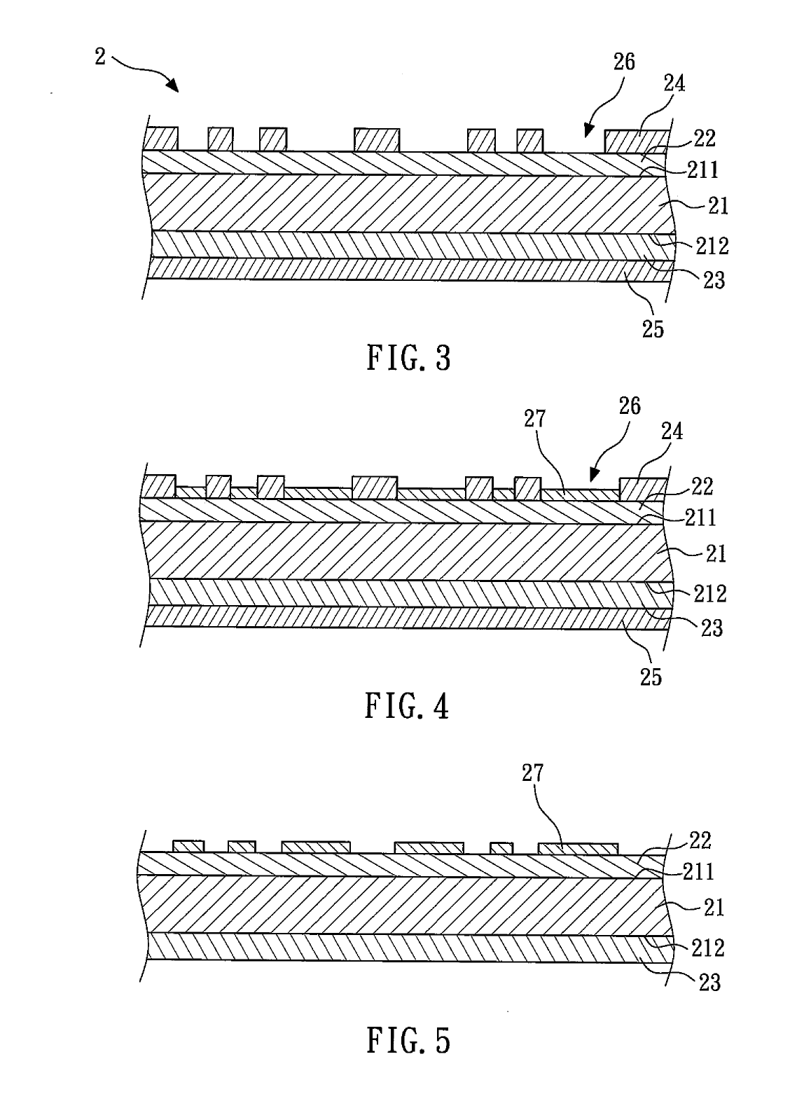

FIGS. 3 to 9 show the schematic views of each step of the method for making a conversion substrate for a leadframe according to a first embodiment of the present invention. First, referring to FIG. 3, a substrate 2 is provided. The substrate 2 has a core layer 21, a first copper layer 22 and a second copper layer 23. The core layer 21 has a first surface 211 and a second surface 212. The first copper layer 22 is disposed on the first surface 211 of the core layer 21. The second copper layer 23 is disposed on the second surface 212 of the core layer 21.

Afterward, a first dry film 24 is formed on the first copper layer 22, and a second dry film 25 is formed on the second copper layer 23. Then, the first dry film 24 is exposed and developed, so as to remove parts of the first dry film 24, and a first pattern 26 is formed, so as to expose parts of the first copper layer 22.

Referring to FIG. 4, a metal is electroplated on the first copper layer 22 in the first pattern 26, so as to form a first metal plating layer 27. In the embodiment, the first metal plating layer 27 is an Ni/Au plating layer.

Referring to FIG. 5, the first dry film 24 and the second dry film 25 are removed.

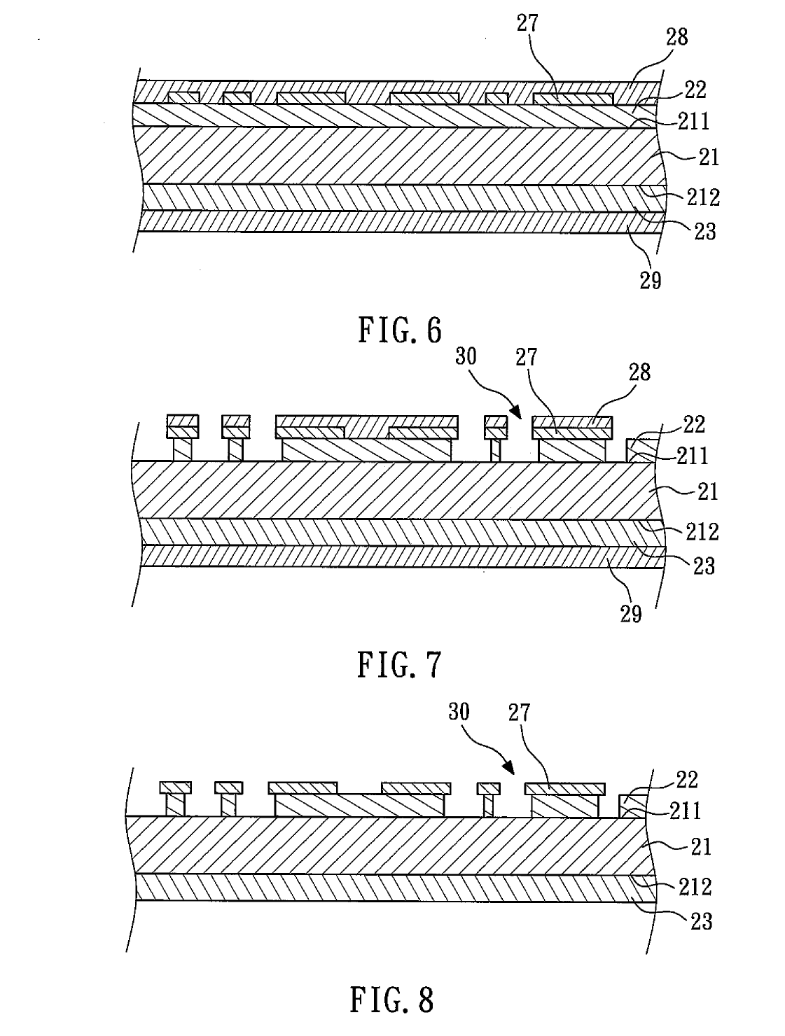

Referring to FIG. 6, a third dry film 28 is formed on the first copper layer 22 and the first metal plating layer 27, and a fourth dry film 29 is formed on the second copper layer 23.

Referring to FIG. 7, the third dry film 28 is exposed and developed, so as to remove parts of the third dry film 28, and a second pattern 30 is formed, so as to expose parts of the first copper layer 22. Afterward, the first copper layer 22 in the second pattern 30 is etched.

Referring to FIG. 8, the third dry film 28 and the fourth dry film 29 are removed.

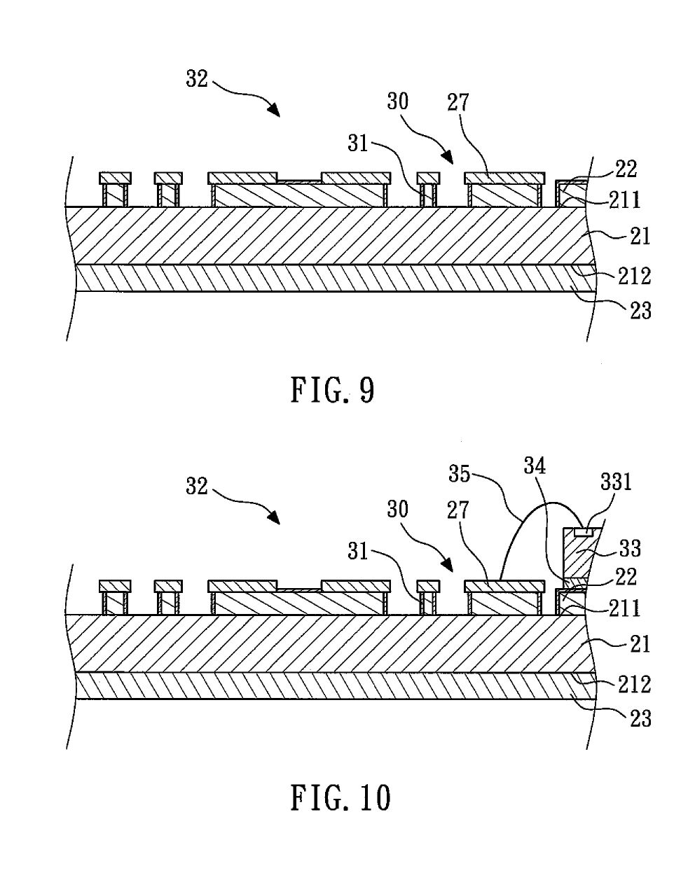

Referring to FIG. 9, a first brown/black oxide layer 31 is formed on the first copper layer 22, so as to cover and protect the first copper layer 22, and a conversion substrate 32 is formed.

FIG. 10 shows a schematic view of application of the conversion substrate for a leadframe according to the first embodiment of the present invention. The conversion substrate 32 is mounted on a die pad (not shown) of the leadframe. The conversion substrate 32 comprises a core layer 21, a first copper layer 22, a second copper layer 23, a first metal plating layer 27 and a first brown/black oxide layer 31.

The core layer 21 has a first surface 211 and a second surface 212. The first copper layer 22 has a plurality of discontinuous sections, and is disposed on the first surface 211 of the core layer 21. The second copper layer 23 is disposed on the second surface 212 of the core layer 21. The first metal plating layer 27 has a plurality of discontinuous sections, and is disposed on the first copper layer 22. The first brown/black oxide layer 31 is disposed on the first copper layer 22, so as to cover the parts of the first copper layer 22 which are not covered by the first metal plating layer 27, and protect the first copper layer 22.

During the application, a die 33 is disposed on the conversion substrate 32, and is adhered to the first brown/black oxide layer 31 over the first copper layer 22 via an adhesive 34 (the die 33 is not disposed on the first metal plating layer 27). The die 33 has a plurality of pads 331, and the pads 331 are electrically connected to the first metal plating layer 27 via a plurality of wires 35.

In the present invention, the polymeric solder mask is not used, so that the metal plating layer will not be polluted, and the yield rate can be raised.

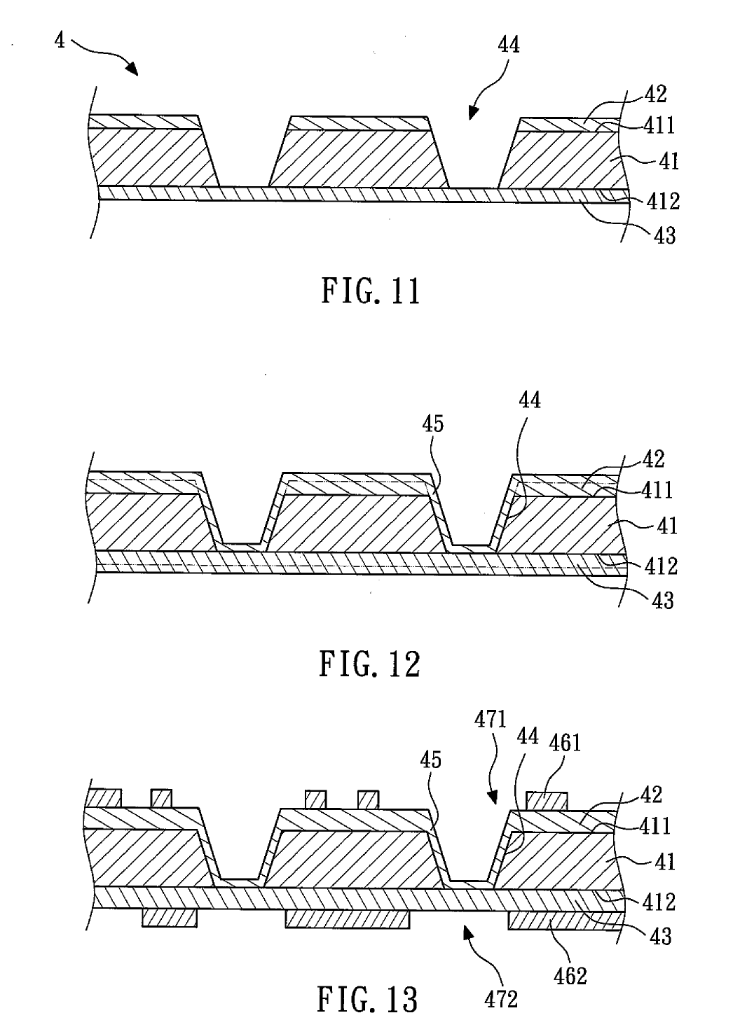

FIGS. 11 to 19 show the schematic views of each step of the method for making a conversion substrate for a leadframe according to a second embodiment of the present invention. First, referring to FIG. 11, a substrate 4 is provided. The substrate 4 has a core layer 41, a first copper layer 42 and a second copper layer 43. The core layer 41 has a first surface 411 and a second surface 412. The first copper layer 42 is disposed on the first surface 411 of the core layer 41. The second copper layer 43 is disposed on the second surface 412 of the core layer 41. Afterward, at least one hole 44 is formed. The hole 44 is a blind hole, and penetrates the first copper layer 42 and the core layer 41 but not the second copper layer 43.

Referring to FIG. 12, a third copper layer 45 is electroplated on the first copper layer 42 and the second copper layer 43, so as to increase the thickness of the first copper layer 42 and the second copper layer 43, and they are still designated as first copper layer 42 and second copper layer 43 hereinafter. The third copper layer 45 is attached to the side wall and the bottom of the hole 44 to electrically connect the first copper layer 42 and the second copper layer 43.

Referring to FIG. 13, a first dry film 461 is formed on the first copper layer 42, and a second dry film 462 is formed on the second copper layer 43. Afterward, the first dry film 461 and the second dry film 462 are exposed and developed, so as to remove parts of the first dry film 461 and parts of the second dry film 462, and a first pattern 471 and a second pattern 472 are formed, so as to expose parts of the first copper layer 42 and parts of the second copper layer 43.

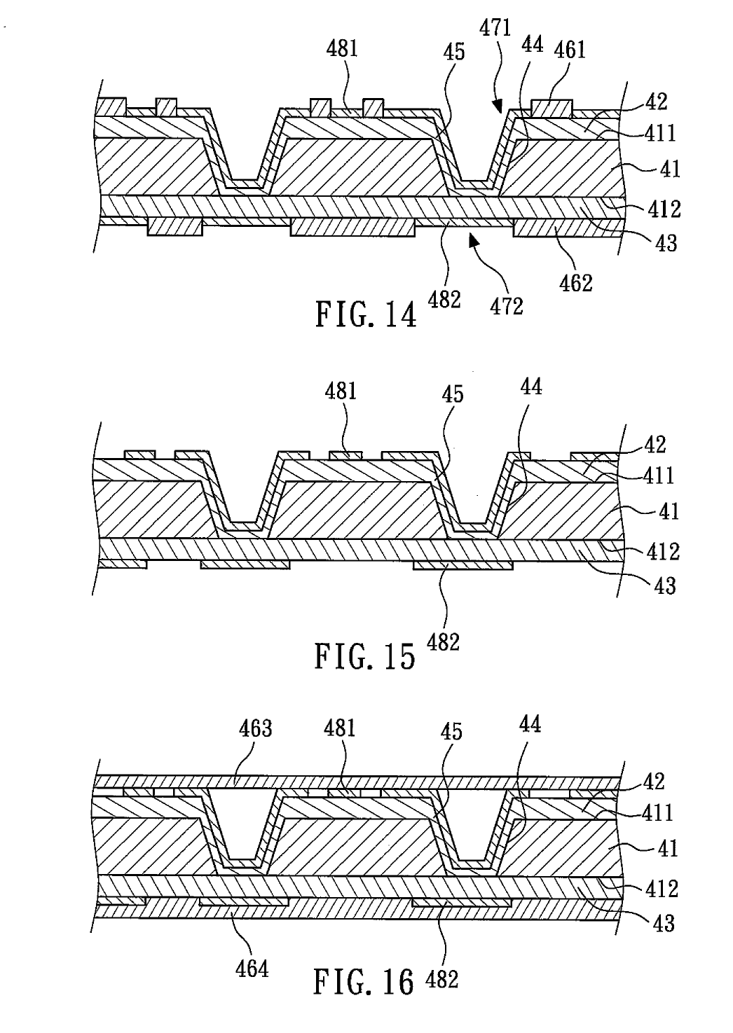

Referring to FIG. 14, a metal is electroplated on the first copper layer 42 in the first pattern 471 and the second copper layer 43 in the second pattern 472, so as to form a first metal plating layer 481 and a second metal plating layer 482. In the embodiment, the first metal plating layer 481 and the second metal plating layer 482 are Ni/Au plating layers.

Referring to FIG. 15, the first dry film 461 and the second dry film 462 are removed.

Referring to FIG. 16, a third dry film 463 is formed on the first copper layer 42 and the first metal plating layer 481, and a fourth dry film 464 is formed on the second copper layer 43 and the second metal plating layer 482.

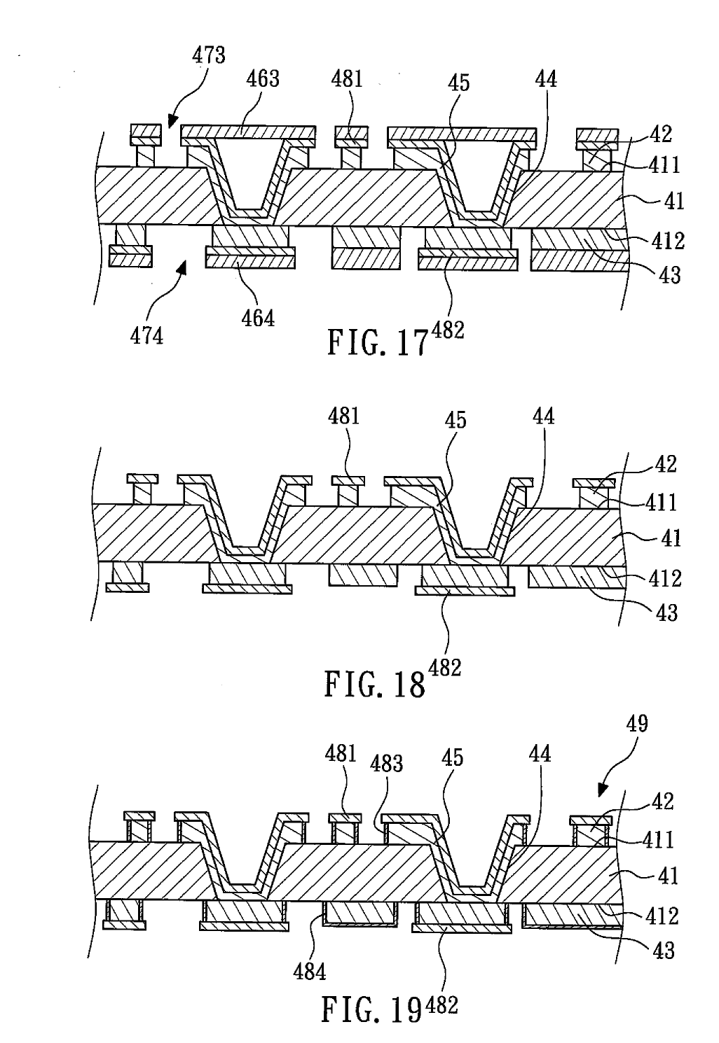

Referring to FIG. 17, the third dry film 463 and the fourth dry film 464 are exposed and developed, so as to remove parts of the third dry film 463 and parts of the fourth dry film 464, and a third pattern 473 and a fourth pattern 474 are formed, so as to expose parts of the first copper layer 42 and parts of the second copper layer 43. Afterward, the first copper layer 42 in the third pattern 473 and the second copper layer 43 in the fourth pattern 474 are etched.

Referring to FIG. 18, the third dry film 463 and the fourth dry film 464 are removed.

Referring to FIG. 19, a first brown/black oxide layer 483 is formed on the first copper layer 42, so as to cover and protect the first copper layer 42. Meanwhile, a second brown/black oxide layer 484 is formed on the second copper layer 43, so as to cover and protect the second copper layer 43, and a conversion substrate 49 is formed.

Referring to FIG. 19 again, the schematic view of a conversion substrate for a leadframe according to a second embodiment of the present invention is shown. The conversion substrate 49 comprises a core layer 41, a first copper layer 42, a second copper layer 43, at least one hole 44, a third copper layer 45, a first metal plating layer 481, a second metal plating layer 482, a first brown/black oxide layer 483 and a second brown/black oxide layer 484. The core layer 41 has a first surface 411 and a second surface 412. The first copper layer 42 has a plurality of discontinuous sections, and is disposed on the first surface 411 of the core layer 41. The second copper layer 43 is disposed on the second surface 412 of the core layer 41. The hole 44 is a blind hole, and penetrates the first copper layer 42 and the core layer 41 but not the second copper layer 43. The third copper layer 45 is attached to the side wall and the bottom of the hole 44 to electrically connect the first copper layer 42 and the second copper layer 43.

The first metal plating layer 481 has a plurality of discontinuous sections, and is disposed on the first copper layer 42. The second metal plating layer 482 has a plurality of discontinuous sections, and is disposed on the second copper layer 43. The first brown/black oxide layer 483 is disposed on the first copper layer 42, so as to cover and protect the first copper layer 42. The second brown/black oxide layer 484 is disposed on the second copper layer 43, so as to cover and protect the second copper layer 43. Similarly, during the application, a die is disposed on the conversion substrate 49, and more particularly on the first brown/black oxide layer 483 over the first copper layer 42 (the die is not disposed on the first metal plating layer 481). The die is electrically connected to the first metal plating layer 481 via a plurality of wires.

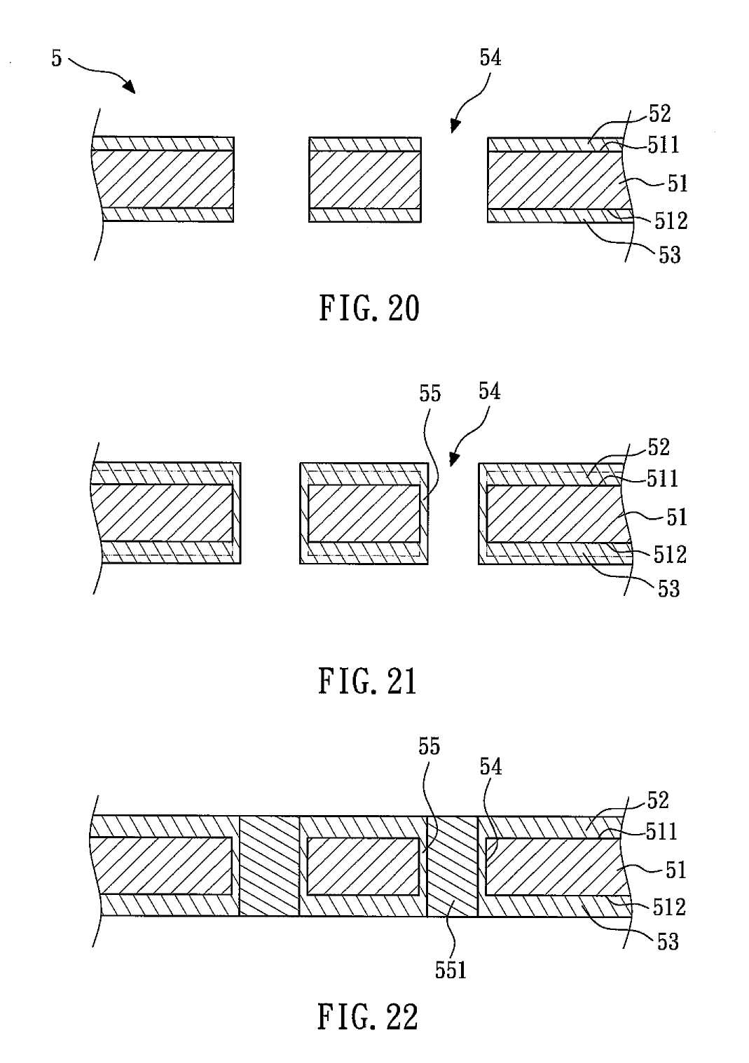

FIGS. 20 to 29 show the schematic views of each step of the method for malting a conversion substrate for a leadframe according to a third embodiment of the present invention. First, referring to FIG. 20, a substrate 5 is provided. The substrate 5 has a core layer 51, a first copper layer 52, and a second copper layer 53. The core layer 51 has a first surface 511 and a second surface 512. The first copper layer 52 is disposed on the first surface 511 of the core layer 51. The second copper layer 53 is disposed on the second surface 512 of the core layer 51. Afterward, at least one hole 54 is formed. The hole 54 is a through hole, and penetrates the first copper layer 52, the core layer 51 and the second copper layer 53.

Referring to FIG. 21, a third copper layer 55 is electroplated on the first copper layer 52 and the second copper layer 53, so as to increase the thickness of the first copper layer 52 and the second copper layer 53, and they are still designated as first copper layer 52 and second copper layer 53 hereinafter. The third copper layer 55 is attached to the side wall of the hole 54 to electrically connect the first copper layer 52 and the second copper layer 53.

Referring to FIG. 22, the through hole 54 is filled up with a filler 551. The filler 551 is preferably further performed with a polishing process, so that the top end and the bottom end of the filler 551 are at the same level with the first copper layer 52 and the second copper layer 53, respectively.

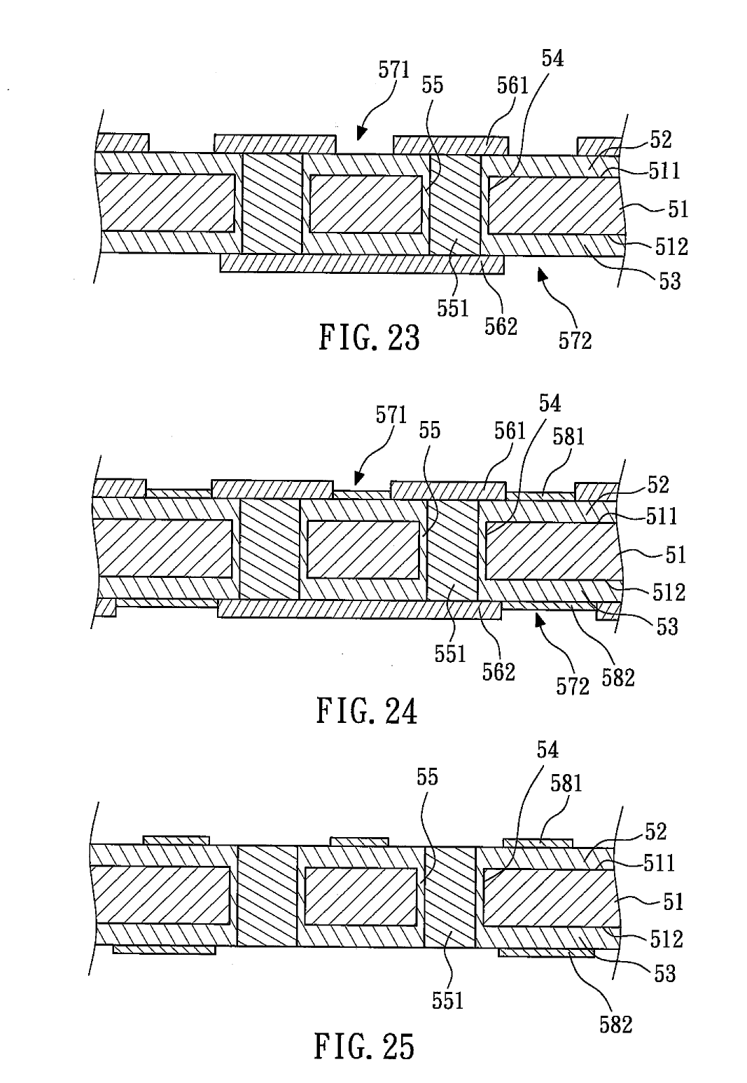

Referring to FIG. 23, a first dry film 561 is formed on the first copper layer 52, and a second dry film 562 is formed on the second copper layer 53. Afterward, the first dry film 561 and the second dry film 562 are exposed and developed, so as to remove parts of the first dry film 561 and parts of the second dry film 562, and a first pattern 571 and a second pattern 572 are formed, so as to expose parts of the first copper layer 52 and parts of the second copper layer 53.

Referring to FIG. 24, a metal is electroplated on the first copper layer 52 in the first pattern 571 and the second copper layer 53 in the second pattern 572, so as to form a first metal plating layer 581 and a second metal plating layer 582.

Referring to FIG. 25, the first dry film 561 and the second dry film 562 are removed.

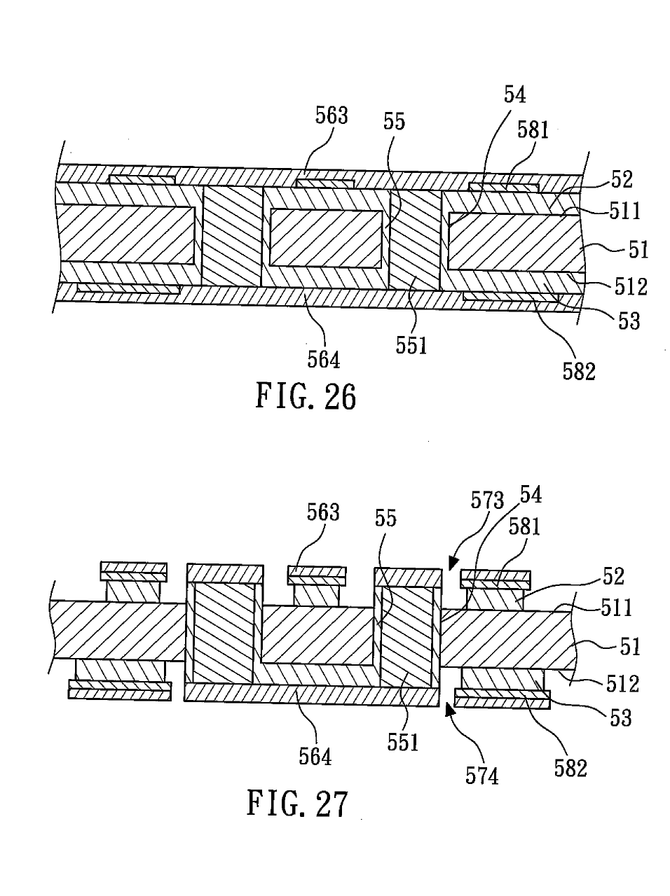

Referring to FIG. 26, a third dry film 563 is formed on the first copper layer 52 and the first metal plating layer 581, and a fourth dry film 564 is formed on the second copper layer 53 and the second metal plating layer 582.

Referring to FIG. 27, the third dry film 563 and the fourth dry film 564 are exposed and developed, so as to remove parts of the third dry film 563 and parts of the fourth dry film 564, and a third pattern 573 and a fourth pattern 574 are formed, so as to expose parts of the first copper layer 52 and parts of the second copper layer 53. Afterward, the first copper layer 52 in the third pattern 573 and the second copper layer 53 in the fourth pattern 574 are etched.

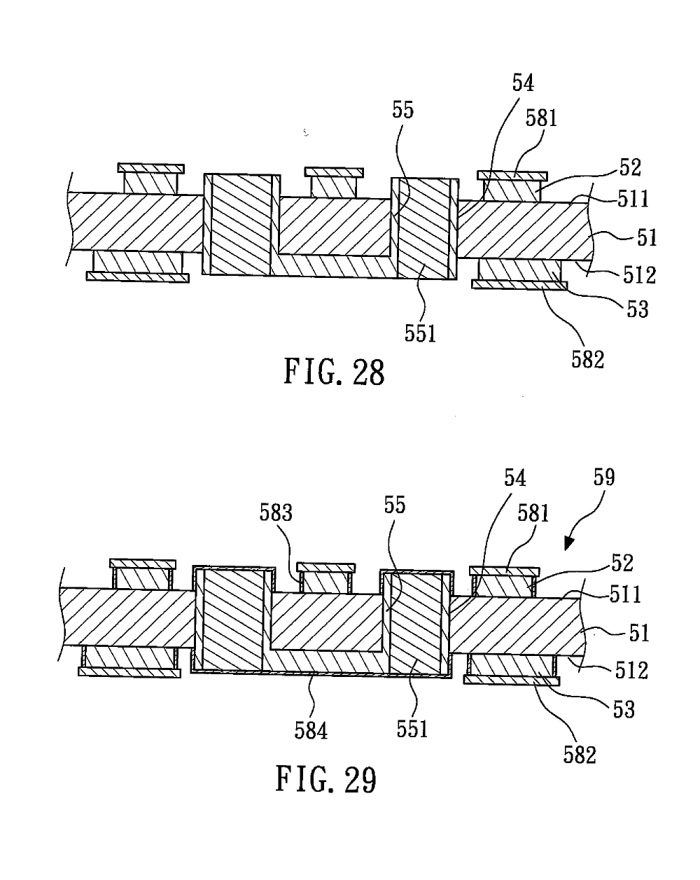

Referring to FIG. 28, the third dry film 563 and the fourth dry film 564 are removed.

Referring to FIG. 29, a first brown/black oxide layer 583 is formed on the first copper layer 52, so as to cover and protect the first copper layer 52. Meanwhile, a second brown/black oxide layer 584 is formed on the second copper layer 53, so as to cover and protect the second copper layer 53, and a conversion substrate 59 is formed.

Referring to FIG. 29 again, the schematic view of a conversion substrate for a leadframe according to a third embodiment of the present invention is shown. The conversion substrate 59 comprises a core layer 51, a first copper layer 52, a second copper layer 53, at least one hole 54, a third copper layer 55, a filler 551, a first metal plating layer 581, a second metal plating layer 582, a first brown/black oxide layer 583 and a second brown/black oxide layer 584. The core layer 51 has a first surface 511 and a second surface 512. The first copper layer 52 has a plurality of discontinuous sections, and is disposed on the first surface 511 of the core layer 51. The second copper layer 53 is disposed on the second surface 512 of the core layer 51. The hole 54 is a through hole, and penetrates the first copper layer 52, the core layer 51 and the second copper layer 53. The third copper layer 55 is attached to the side wall of the hole 54 to electrically connect the first copper layer 52 and the second copper layer 53. The filler 551 fills up the hole 54.

The first metal plating layer 581 has a plurality of discontinuous sections, and is disposed on the first copper layer 52. The second metal plating layer 582 has a plurality of discontinuous sections, and is disposed on the second copper layer 53. The first brown/black oxide layer 583 is disposed on the first copper layer 52, so as to cover and protect the first copper layer 52. The second brown/black oxide layer 584 is disposed on the second copper layer 53, so as to cover and protect the second copper layer 53. Similarly, during the application, a die is disposed on the conversion substrate 59, and more particularly on the first brown/black oxide layer 583 over the first copper layer 52 (the die is not disposed on the first metal plating layer 581). The die is electrically connected to the first metal plating layer 581 via a plurality of wires.

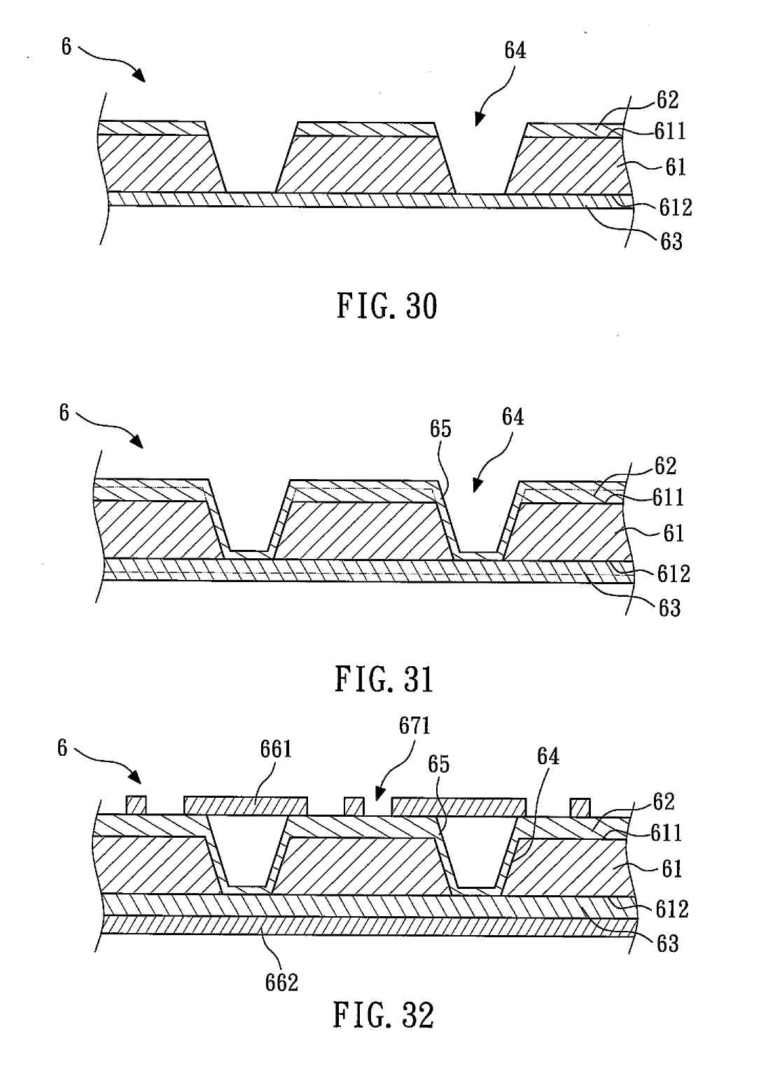

FIGS. 30 to 40 show the schematic views of each step of the method for making a conversion substrate for a leadframe according to a fourth embodiment of the present invention. First, referring to FIG. 30, a substrate 6 is provided. The substrate 6 has a core layer 61, a first copper layer 62 and a second copper layer 63. The core layer 61 has a first surface 611 and a second surface 612. The first copper layer 62 is disposed on the first surface 611 of the core layer 61. The second copper layer 63 is disposed on the second surface 612 of the core layer 61. Afterward, at least one hole 64 is formed. The hole 64 is a blind hole, and penetrates the first copper layer 62 and the core layer 61 but not the second copper layer 63.

Referring to FIG. 31, a third copper layer 65 is electroplated on the first copper layer 62 and the second copper layer 63, so as to increase the thickness of the first copper layer 62 and the second copper layer 63, and they are still designated as first copper layer 62 and second copper layer 63 hereinafter. The third copper layer 65 is attached to the side wall and the bottom of the hole 64 to electrically connect the first copper layer 62 and the second copper layer 63.

Referring to FIG. 32, a first dry film 661 is formed on the first copper layer 62, and a second dry film 662 is formed on the second copper layer 63. Afterward, the first dry film 661 is exposed and developed, so as to remove parts of the first dry film 661, and a first pattern 671 is formed, so as to expose parts of the first copper layer 62.

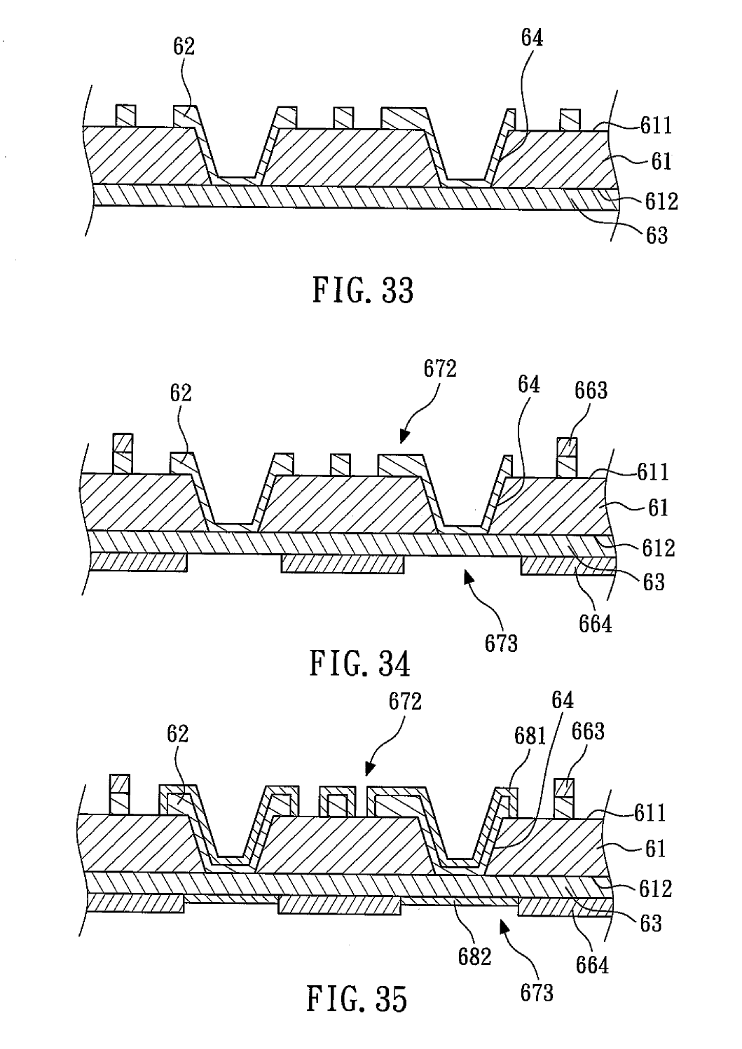

Referring to FIG. 33, the first copper layer 62 in the first pattern 671 is etched. Afterward, the first dry film 661 and the second dry film 662 are removed.

Referring to FIG. 34, a third dry film 663 is formed on the first copper layer 62, and a fourth dry film 664 is formed on the second copper layer 63. Afterward, the third dry film 663 and the fourth dry film 664 are exposed and developed, so as to remove parts of the third dry film 663 and the fourth dry film 664, and a second pattern 672 and a third pattern 673 are formed, so as to expose parts of the first copper layer 62 and parts of the second copper layer 63.

Referring to FIG. 35, a metal is electroplated on the first copper layer 62 in the second pattern 672 and the second copper layer 63 in the third pattern 673, so as to form a first metal plating layer 681 and a second metal plating layer 682.

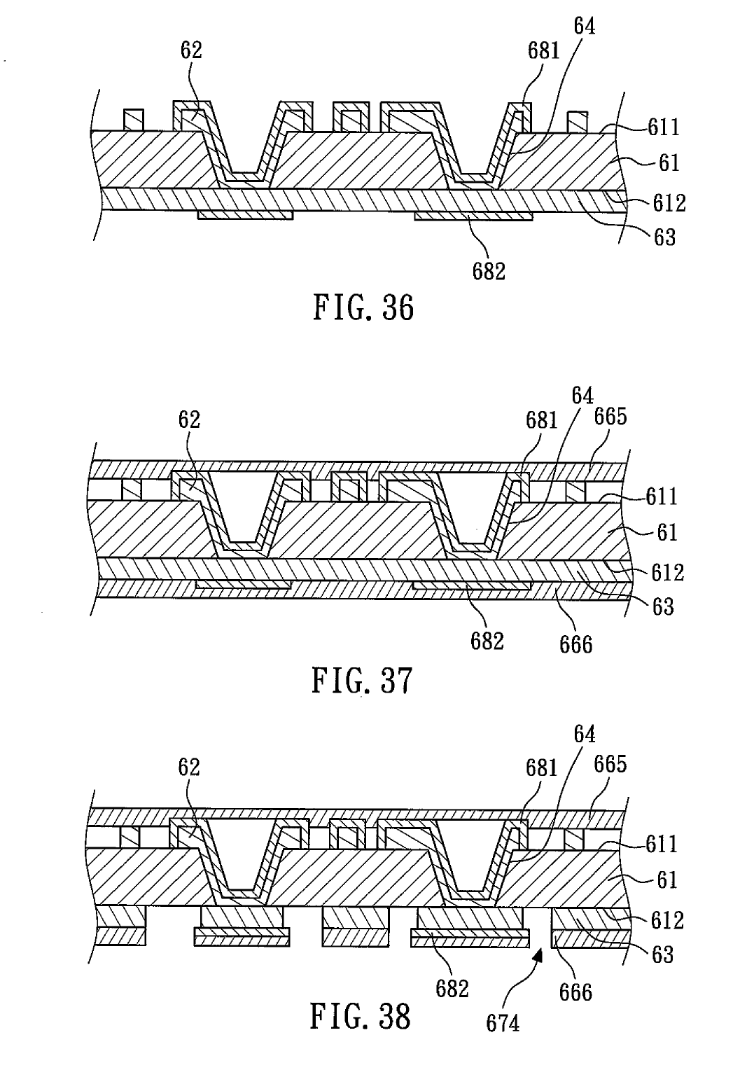

Referring to FIG. 36, the third dry film 663 and the fourth dry film 664 are removed.

Referring to FIG. 37, a fifth dry film 665 is formed on the first copper layer 62 and the first metal plating layer 681, and a sixth dry film 666 is formed on the second copper layer 63 and the second metal plating layer 682.

Referring to FIG. 38, the sixth dry film 666 is exposed and developed, so as to remove parts of the sixth dry film 666, and a fourth pattern 674 is formed, so as to expose parts of the second copper layer 63. Afterward, the second copper layer 63 in the fourth pattern 674 is etched.

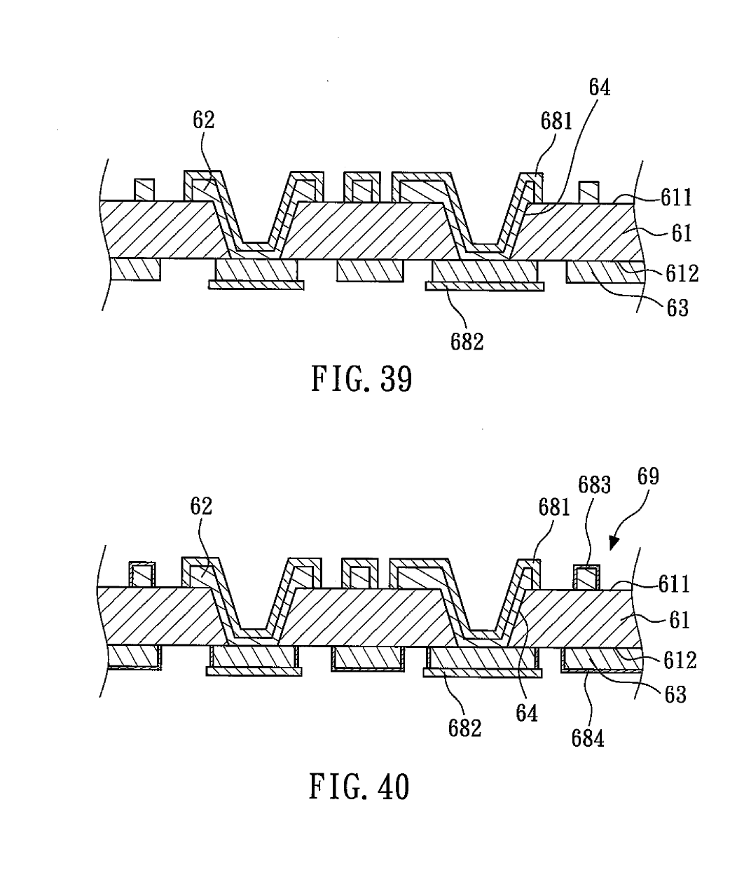

Referring to FIG. 39, the fifth dry film 665 and the sixth dry film 666 are removed.

Referring to FIG. 40, a first brown/black oxide layer 683 is formed on the first copper layer 62, so as to cover and protect the first copper layer 62. Meanwhile, a second brown/black oxide layer 684 is formed on the second copper layer 63, so as to cover and protect the second copper layer 63, and a conversion substrate 69 is formed.

Referring to FIG. 40 again, the schematic view of a conversion substrate for a leadframe according to a fourth embodiment of the present invention is shown. The conversion substrate 69 comprises a core layer 61, a first copper layer 62, a second copper layer 63, at least one hole 64, a third copper layer 65, a first metal plating layer 681, a second metal plating layer 682, a first brown/black oxide layer 683 and a second brown/black oxide layer 684. The core layer 61 has a first surface 611 and a second surface 612. The first copper layer 62 has a plurality of discontinuous sections, and is disposed on the first surface 611 of the core layer 61. The second copper layer 63 is disposed on the second surface 612 of the core layer 61. The hole 64 is a blind hole, and penetrates the first copper layer 62 and the core layer 61 but not the second copper layer 63. The third copper layer 65 is attached to the side wall and the bottom of the hole 64 to electrically connect the first copper layer 62 and the second copper layer 63.

The first metal plating layer 681 has a plurality of discontinuous sections, and is disposed on the first copper layer 62. The second metal plating layer 682 has a plurality of discontinuous sections, and is disposed on the second copper layer 63. The first brown/black oxide layer 683 is disposed on the first copper layer 62, so as to cover and protect the first copper layer 62. The second brown/black oxide layer 684 is disposed on the second copper layer 63, so as to cover and protect the second copper layer 63. Similarly, during the application, a die is disposed on the conversion substrate 69, and more particularly on the first brown/black oxide layer 683 over the first copper layer 62 (the die is not disposed on the first metal plating layer 681). The die is electrically connected to the first metal plating layer 681 via a plurality of wires.

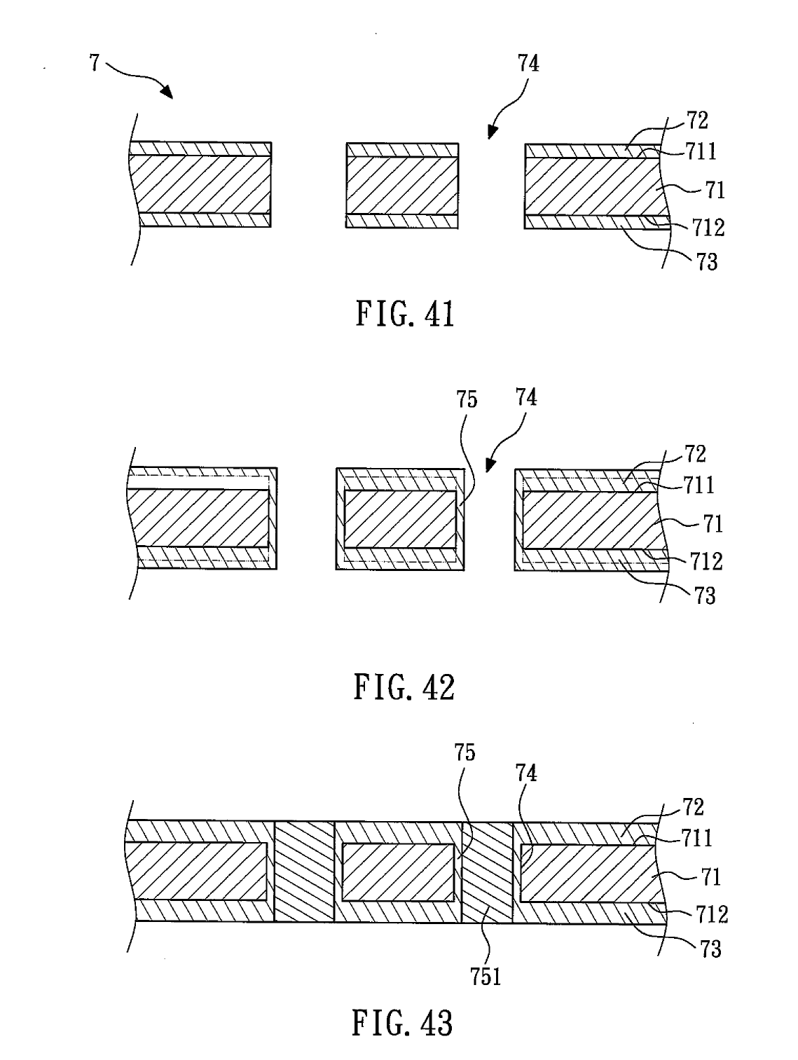

FIGS. 41 to 53 show the schematic views of each step of the method for making a conversion substrate for a leadframe according to a fifth embodiment of the present invention. First, referring to FIG. 41, a substrate 7 is provided. The substrate 7 has a core layer 71, a first copper layer 72 and a second copper layer 73. The core layer 71 has a first surface 711 and a second surface 712. The first copper layer 72 is disposed on the first surface 711 of the core layer 71. The second copper layer 73 is disposed on the second surface 712 of the core layer 71. Afterward, at least one hole 74 is formed. The hole 74 is a through hole, and penetrates the first copper layer 72, the core layer 71 and the second copper layer 73.

Referring to FIG. 42, a third copper layer 75 is electroplated on the first copper layer 72 and the second copper layer 73, so as to increase the thickness of the first copper layer 72 and the second copper layer 73, and they are still designated as first copper layer 72 and second copper layer 73 hereinafter. The third copper layer 75 is attached to the side wall of the hole 74 to electrically connect the first copper layer 72 and the second copper layer 73.

Referring to FIG. 43, the through hole 74 is filled up with a filler 751. The filler 751 is preferably further performed with a polishing process, so that the top end and the bottom end of the filler 751 are at the same level with the first copper layer 72 and the second copper layer 73, respectively.

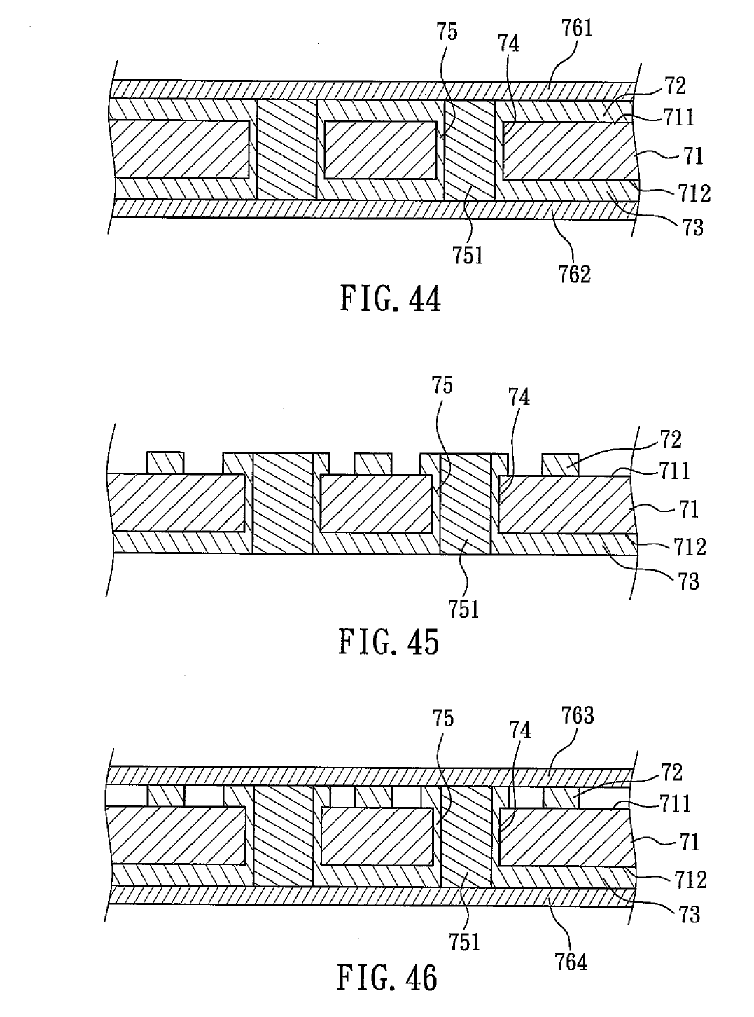

Referring to FIG. 44, a first dry film 761 is formed on the first copper layer 72, and a second dry film 762 is formed on the second copper layer 73.

Referring to FIG. 45, the first dry film 761 is exposed and developed, so as to remove parts of the first dry film 761, and a first pattern is formed, so as to expose parts of the first copper layer 72. Afterward, the first copper layer 72 in the first pattern is etched. Afterward, the first dry film 761 and the second dry film 762 are removed.

Referring to FIG. 46, a third dry film 763 is formed on the first copper layer 72, and a fourth dry film 764 is formed on the second copper layer 73.

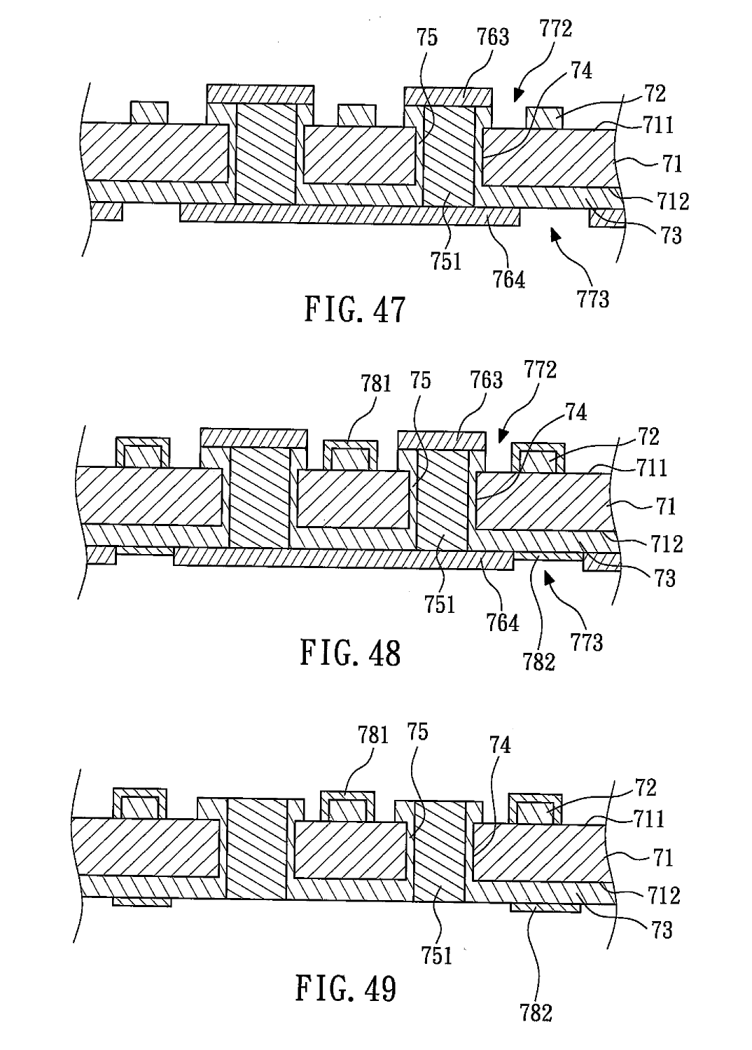

Referring to FIG. 47, the third dry film 763 and the fourth dry film 764 are exposed and developed, so as to remove parts of the third dry film 763 and parts of the fourth dry film 764, and a second pattern 772 and a third pattern 773 are formed, so as to expose parts of the first copper layer 72 and parts of the second copper layer 73.

Referring to FIG. 48, a metal is electroplated on the first copper layer 72 in the second pattern 772 and the second copper layer 73 in the third pattern 773, so as to form a first metal plating layer 781 and a second metal plating layer 782.

Referring to FIG. 49, the third dry film 763 and the fourth dry film 764 are removed.

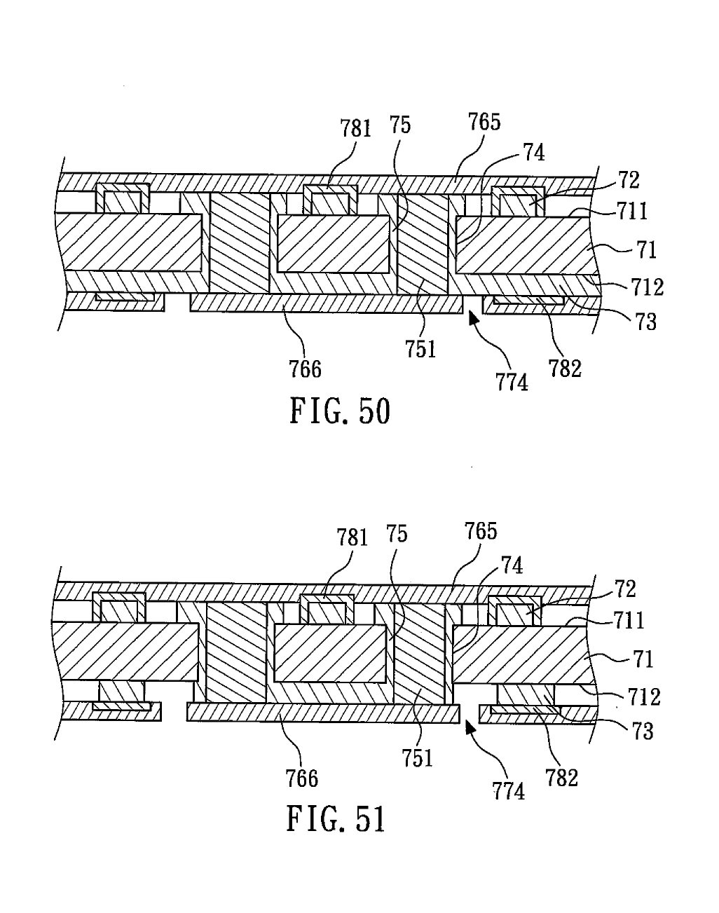

Referring to FIG. 50, a fifth dry film 765 is formed on the first copper layer 72 and the first metal plating layer 781, and a sixth dry film 766 is formed on the second copper layer 73 and the second metal plating layer 782. Afterward, the sixth dry film 766 is exposed and developed, so as to remove parts of the sixth dry film 766, and a fourth pattern 774 is formed, so as to expose parts of the second copper layer 73.

Referring to FIG. 51, the second copper layer 73 in the fourth pattern 774 is etched.

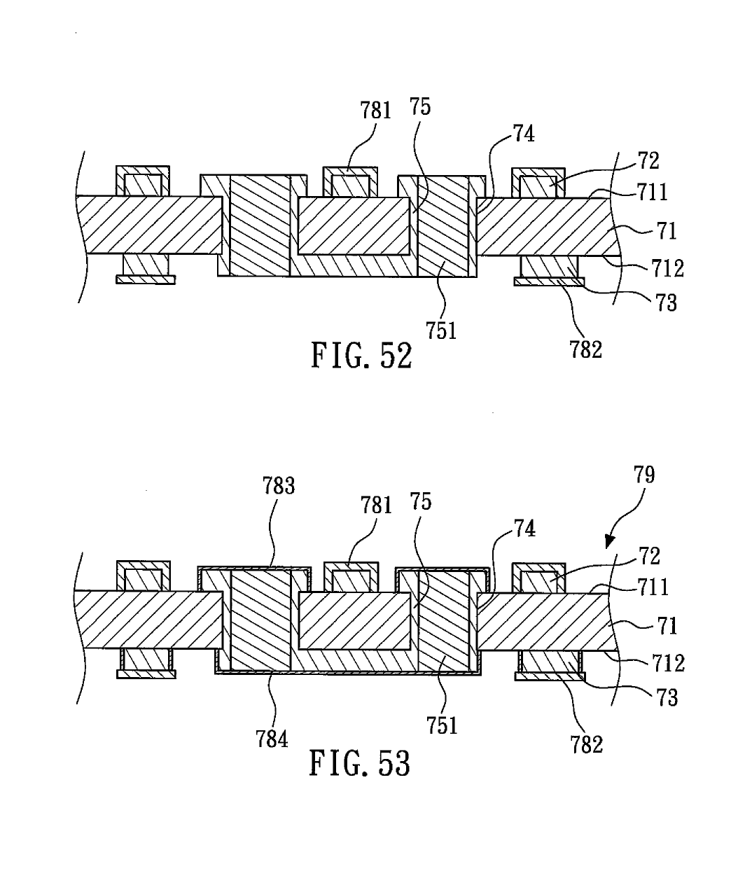

Referring to FIG. 52, the fifth dry film 765 and the sixth dry film 766 are removed.

Referring to FIG. 53, a first brown/black oxide layer 783 is formed on the first copper layer 72, so as to cover and protect the first copper layer 72. Meanwhile, a second brown/black oxide layer 784 is formed on the second copper layer 73, so as to cover and protect the second copper layer 73, and a conversion substrate 79 is formed.

Referring to FIG. 52 again, the schematic view of a conversion substrate for a leadframe according to a fifth embodiment of the present invention is shown. The conversion substrate 79 comprises a core layer 71, a first copper layer 72, a second copper layer 73, at least one hole 74, a filler 751, a third copper layer 75, a first metal plating layer 781, a second metal plating layer 782, a first brown/black oxide layer 783 and a second brown/black oxide layer 784. The core layer 71 has a first surface 711 and a second surface 712. The first copper layer 72 has a plurality of discontinuous sections, and is disposed on the first surface 711 of the core layer 71. The second copper layer 73 is disposed on the second surface 712 of the core layer 71. The hole 74 is a through hole, and penetrates the first copper layer 72, the core layer 71 and the second copper layer 73. The third copper layer 75 is attached to the side wall of the hole 74 to electrically connect the first copper layer 72 and the second copper layer 73. The filler 751 fills up the hole 74.

The first metal plating layer 781 has a plurality of discontinuous sections, and is disposed on the first copper layer 72. The second metal plating layer 782 has a plurality of discontinuous sections, and is disposed on the second copper layer 73. The first brown/black oxide layer 783 is disposed on the first copper layer 72, so as to cover and protect the first copper layer 72. The second brown/black oxide layer 784 is disposed on the second copper layer 73, so as to cover and protect the second copper layer 73. Similarly, during the application, a die is disposed on the conversion substrate 79, and more particularly on the first brown/black oxide layer 783 over the first copper layer 72 (the die is not disposed on the first metal plating layer 781). The die is electrically connected to the first metal plating layer 781 via a plurality of wires.

While several embodiments of the present invention have been illustrated and described, various modifications and improvements can be made by those skilled in the art. The embodiments of the present invention are therefore described in an illustrative but not restrictive sense. It is intended that the present invention should not be limited to the particular forms as illustrated, and that all modifications which maintain the spirit and scope of the present invention are within the scope defined in the appended claims.

What is claimed is:

1. A conversion substrate mounted on a die pad of a leadframe, the conversion substrate comprising:
a core layer, having a first surface and a second surface;
a first copper layer, having a plurality of discontinuous sections, and disposed on the first surface of the core layer;
a first metal plating layer, having a plurality of discontinuous sections, and disposed on the first copper layer; and
a first brown/black oxide layer, disposed on the first copper layer, so as to protect the first copper layer.

2. The conversion substrate as claimed in claim 1, further comprising:
a second copper layer, disposed on the second surface of the core layer; and
a second brown/black oxide layer, disposed on the second copper layer, so as to protect the second copper layer.

3. The conversion substrate as claimed in claim 2, further comprising a second metal plating layer disposed on the second copper layer.

4. The conversion substrate as claimed in claim 1, wherein the first metal plating layer is an Ni/Au plating layer.

5. The conversion substrate as claimed in claim 2, further comprising at least one blind hole and a third copper layer, wherein the blind hole penetrates the first copper layer and the core layer but not the second copper layer, and the third copper layer is attached to the side wall and the bottom of the blind hole to electrically connect the first copper layer and the second copper layer.

6. The conversion substrate as claimed in claim 2, further comprising at least one through hole, a third copper layer and a filler, wherein the through hole penetrates the first copper layer, the core layer and the second copper layer, the third copper layer is attached to the side wall of the through hole to electrically connect the first copper layer and the second copper layer, and the filler fills up the through hole.

7. The conversion substrate as claimed in claim 1, further comprising a die disposed on the first brown/black oxide layer, and electrically connected to the first metal plating layer.

8. The conversion substrate as claimed in claim 7, further comprising a plurality of wires that electrically connects the die and the first metal plating layer.

9. A method for making a conversion substrate for a leadframe, the conversion substrate being mounted on a die pad of the leadframe, and the method comprises the steps of:
(a) providing a substrate having a core layer and a first copper layer, wherein the core layer has a first surface and a second surface, and the first copper layer is disposed on the first surface of the core layer;
(b) forming a first metal plating layer on the first copper layer; and
(c) forming a first brown/black oxide layer on the first copper layer to protect the first copper layer.

10. The method as claimed in claim 9, wherein in Step (a), the substrate further has a second copper layer disposed on the second surface of the core layer, Step (b) further comprises a step of forming a second metal plating layer on the second copper layer, and Step (c) further comprises a step of forming a second brown/black oxide layer on the second copper layer to protect the second copper layer.

11. The method as claimed in claim 10, wherein Step (b) comprises the steps of:
(b1) forming a first dry film on the first copper layer and a second dry film on the second copper layer;
(b2) exposing and developing the first dry film, so as to remove parts of the first dry film, and forming a first pattern, so as to expose parts of the first copper layer;
(b3) electroplating a metal on the first copper layer in the first pattern, so as to form the first metal plating layer;
(b4) removing the first dry film and the second dry film;
(b5) forming a third dry film on the first copper layer and the first metal plating layer, and forming a fourth dry film on the second copper layer;
(b6) exposing and developing the third dry film, so as to remove parts of the third dry film, and forming a second pattern, so as to expose parts of the first copper layer;
(b7) etching the first copper layer in the second pattern; and
(b8) removing the third dry film and the fourth dry film.

12. The method as claimed in claim 11, further comprising a step of electroplating a third copper layer on the first copper layer and the second copper layer, so as to increase the thickness of the first copper layer and the second copper layer after Step (a).

13. The method as claimed in claim 10, further comprising, after Step (a), the steps of:
(a1) forming at least one hole, the hole penetrating the first copper layer and the core layer; and
(a2) electroplating a third copper layer on the first copper layer and the second copper layer, so as to increase the thickness of the first copper layer and the second copper layer, the third copper layer being attached to the side wall of the hole to electrically connect the first copper layer and the second copper layer.

14. The method as claimed in claim 13, wherein in Step (a1), the hole is a blind hole, and penetrates the first copper layer and the core layer but not the second copper layer.

15. The method as claimed in claim 13, wherein in Step (a1), the hole is a through hole, and penetrates the first copper layer, the core layer and the second copper layer, and after Step (a2), further comprises a step of filling up the through hole with a filler.

16. The method as claimed in claim 13, wherein Step (b) comprises the steps of:
(b1) forming a first dry film on the first copper layer and a second dry film on the second copper layer;
(b2) exposing and developing the first dry film and the second dry film, so as to remove parts of the first dry film and parts of the second dry film, and forming a first pattern and a second pattern, so as to expose parts of the first copper layer and parts of the second copper layer;
(b3) electroplating a metal on the first copper layer in the first pattern and the second copper layer in the second pattern, so as to form the first metal plating layer and the second metal plating layer;
(b4) removing the first dry film and the second dry film;
(b5) forming a third dry film on the first copper layer and the first metal plating layer, and forming a fourth dry film on the second copper layer and the second metal plating layer;
(b6) exposing and developing the third dry film and the fourth dry film, so as to remove parts of the third dry film and parts of the fourth dry film, and forming a third pattern and a fourth pattern, so as to expose parts of the first copper layer and parts of the second copper layer;
(b7) etching the first copper layer in the third pattern and the second copper layer in the fourth pattern; and
(b8) removing the third dry film and the fourth dry film.

17. The method as claimed in claim 13, wherein Step (b) comprises the steps of:
(b1) forming a first dry film on the first copper layer, and a second dry film on the second copper layer;
(b2) exposing and developing the first dry film, so as to remove parts of the first dry film, and forming a first pattern, so as to expose parts of the first copper layer;
(b3) etching the first copper layer in the first pattern;
(b4) removing the first dry film and the second dry film;
(b5) forming a third dry film on the first copper layer and a fourth dry film on the second copper layer;
(b6) exposing and developing the third dry film and the fourth dry film, so as to remove parts of the third dry film and parts of the fourth dry film, and forming a second pattern and a third pattern, so as to expose parts of the first copper layer and parts of the second copper layer;
(b7) electroplating a metal on the first copper layer in the second pattern and the second copper layer in the third pattern, so as to form the first metal plating layer and the second metal plating layer;
(b8) removing the third dry film and the fourth dry film;
(b9) forming a fifth dry film on the first copper layer and the first metal plating layer, and forming a sixth dry film on the second copper layer and the second metal plating layer;
(b10) exposing and developing the sixth dry film, so as to remove parts of the sixth dry film, and forming a fourth pattern, so as to expose parts of the second copper layer;
(b11) etching the second copper layer in the fourth pattern; and
(b12) removing the fifth dry film and the sixth dry film.
